(19) United States
(12) Patent Application Publication
(10) Pub. No.: US 2026/0258547 A1
(43) Pub. Date: Sep. 3, 2026

(54) HIGH-K AMORPHOUS FLUORINATED CARBON THIN FILM, METHOD OF MANUFACTURING THE SAME, AND SEMICONDUCTOR OR CAPACITOR DEVICE USING THE SAME

(71) Applicant: THE INDUSTRY & ACADEMIC COOPERATION IN CHUNGNAM NATIONAL UNIVERSITY (IAC), Daejeon (KR)

(72) Inventor: Eui-Tae KIM, Daejeon (KR)

(73) Assignee: THE INDUSTRY & ACADEMIC COOPERATION IN CHUNGNAM NATIONAL UNIVERSITY (IAC), Daejeon (KR)

(21) Appl. No.: 18/871,624

(22) PCT Filed: Jun. 5, 2023
(86) PCT No.: PCT/KR2023/007677

§ 371 Date: Dec. 4, 2024

(30) Foreign Application Priority Data
Jun. 9, 2022 (KR) 10-2022-0070060

(51) Int. Cl. C23C 16/26; C23C 16/505; C23C 16/52; H10D 1/66; H10D 1/68; H10D 64/68

(52) U.S. Cl. CPC C23C 16/26; C23C 16/505; C23C 16/52; H10D 1/66; H10D 1/68; H10D 64/68

(57) ABSTRACT

An amorphous fluorinated carbon thin film has a dielectric constant of 10 or more. Fluorine is trapped in dangling bonds of the amorphous carbon thin film. Hydrogen is further trapped in the dangling bonds of the amorphous carbon thin film. The rms surface roughness of the thin film is 5 nm or less. The leakage current is 10 A/cm² or less at an applied voltage of 1 V and an equivalent oxide thickness of 0.1 nm. The dielectric strength is 10 MV/cm or more at an equivalent oxide thickness of 0.1 nm. The CV hysteresis is 5 mV or less.

### CROSS-REFERENCE TO PRIOR APPLICATIONS

This application is a National Stage Patent Application of PCT International Application No. PCT/KR2023/007677 (filed on Jun. 5, 2023), which claims priority to Korean Patent Application No. 10-2022-0070060 (filed on Jun. 9, 2022), which are all hereby incorporated by reference in their entirety.

### BACKGROUND

The present invention relates to an amorphous fluorinated carbon thin film having high dielectric constant, low leakage current, and high dielectric strength useful for manufacturing highly integrated devices, a method of manufacturing the same, and a semiconductor or capacitor device using the same.

The gate length of metal-oxide-semiconductor field-effect (MOSFET), which are crucial in the fabrication of very transistors large-scale integrated circuits (VLSI), has rapidly decreased from 10 μm to 10 nm over the past few decades. As the thickness of SiO₂ gate dielectric decreases, tunneling gate current increases exponentially, causing excessive standby power in integrated circuits, thus the utility of SiO₂ thin films traditionally used as insulating films has reached its limit. Accordingly, with the integration of semiconductor devices such as memory devices and logic devices, development of high-k dielectrics with high dielectric constant, low leakage current, and high dielectric strength is required to replace SiO₂ (k=3.9). Materials having higher dielectric constants than SiO₂ are commonly abbreviated as high-k dielectrics. Ta₂O₄ and Al₂O₃ were initially applied as high-k materials, and after the adoption of sub-100 nm nodes in the late 2000s, alternative metal oxides such as ZrO₂ (k=25), HfO₂ (k=35), Al₂O₃ (k=10), and TiO₂ (k=41) were extensively investigated to reduce gate leakage and power consumption. Currently, research is being conducted in various directions such as finding materials to replace Hf Source (Al, Zr, Ta, STO, BST, etc.) or methods of deposition by adding other materials to Hf Source. These high-k dielectrics can mostly be applied to devices in the form of oxide thin films. However, the high-k layer of metal oxides contains numerous bulk traps such as oxygen vacancies, increasing CV hysteresis and causing threshold voltage instability phenomena. Furthermore, as the device node size decreases to 10 nm units, an equivalent oxide thickness (EOT) of less than 1 nm is required, and under these conditions, electron tunneling can occur in Hf- or Zr-based oxides. Moreover, Hf-based oxides have low crystallization temperatures making them prone to crystallization, show thermal instability when in contact with Si, and have high defect density. Zr-based oxides have high film crystallinity resulting in rough surfaces, and high density of grain boundaries leading to very high leakage current. Ti-based oxide films inherently have a low band gap energy of 3.5 eV, causing problems due to high leakage current and low dielectric strength. Therefore, development of new high-k dielectrics is required for technology with nodes below 10 nm. Organic electronic devices have drawn significant attention due to their potential as large-area, low-cost and flexible devices. Moreover, most organic materials are amorphous or have poor crystallinity, exhibiting smooth surfaces. Carbon thin films are receiving significant attention in technical and industrial applications due to their excellent electrical and mechanical properties. Among organic materials, carbon is the most versatile material, and its electrical properties are directly related to its material structure. That is, the key to carbon's versatility lies in its chemical bonding. σ-bonds between sp³ state carbon atoms are generally insulators. Diamond is a powerful insulator (conductivity <10⁻¹⁵ Ω−1 cm−1) and exhibits very high hardness because carbon atoms are connected by sp³ bonds. On the other hand, when I-bonds associated with sp² state carbon atom groups exist, electrons can be delocalized and used as charge carriers. Graphite forms sp² bonds and, unlike diamond, exhibits high conductivity (10⁴ Ω⁻¹ cm⁻¹).

It is well known that the bonding of carbon materials can be controlled by adjusting the deposition temperature during carbon thin film manufacture. Chemical vapor deposition (CVD) is a widely used method for manufacturing carbon thin films, capable of producing high-quality graphene and carbon nanotubes at high temperatures of about ~1000° C. When the deposition temperature is lowered to about ~700° C. during CVD deposition, nanographite structure is formed, and amorphous carbon is formed at room temperature. Research on carbon-based materials has focused particularly on nanostructures with highly aligned structures such as graphene and carbon nanotubes, which have high potential as transparent conductors or next-generation semiconductors due to their high conductivity characteristics and transparency. As a result, despite nanographite and amorphous carbon also exhibiting several interesting characteristics, attempts to develop materials with new properties utilizing these and apply them have been very limited.

Because nanographite and amorphous carbon contain a considerable proportion of so-called “dangling bonds” meaning fixed free radicals, they form amorphous hydrogenated carbon films by reacting with hydrogen and/or HC radicals under appropriate conditions. Similarly, amorphous fluorinated carbon ((a-C:Fs)) films can be formed in the presence of fluorine and/or FC radicals. Korean Patent No. 10-0283007 reported that when manufacturing amorphous fluorinated carbon by increasing fluorine concentration in amorphous carbon, the dielectric constant can be lowered further compared to amorphous hydrogenated carbon. Accordingly, amorphous fluorinated carbon films have been mainly reported to be used as insulating films (Korean Patents No. 10-0427508, No. 10-0283007, Japanese Patent No. 3666106) utilizing their low dielectric constant characteristics.

### SUMMARY

The present invention aims to solve the problems of the prior art by providing a novel high-k amorphous fluorinated carbon thin film with a high dielectric constant, low leakage current, and high dielectric strength, making it useful for the production of highly integrated devices and a method of manufacturing the same.

The present invention also aims to provide a semiconductor or capacitor device including the above high-k amorphous fluorinated carbon thin film.

To achieve the aforementioned objectives, the present invention relates to an amorphous fluorinated carbon thin film having a dielectric constant of 10 or more.

Throughout the specification, when any part “includes” any component, unless specifically stated otherwise, this means that other components are not excluded but may be further included. Also, when a part such as a layer, film, region, or plate is “on” or “above” another part, this includes not only cases where it is “directly on” the other part but also cases where other parts exist in between. Conversely, when any part is “directly on” another part, it means there are no other parts in between. Furthermore, when any part is formed “entirely” on another part, this includes not only cases where it is formed on the entire surface of the other part but also cases where it is not formed on some edges.

In this specification, “amorphous” is a term used in contrast to “crystalline,” indicating the absence of long-range order in atomic positions. In the carbon thin film of the present invention, carbon may include both sp² and sp³ bonds, but the ratio thereof does not limit the thin film of the present invention.

Also, in this specification, “amorphous fluorinated carbon thin film” refers to an amorphous carbon thin film that contains fluorine trapped in dangling bonds, and does not exclude the presence of other elements trapped by dangling bonds. For example, the amorphous fluorinated carbon thin film of the present invention may further include hydrogen trapped by dangling bonds. In the thin film, fluorine may be bonded in the form of —CF, —CF₂, or —CF₃.

According to conventional technology, amorphous carbon thin films were known to be low-k thin films with very low dielectric constants, and when fluorine was incorporated into amorphous carbon thin films, the dielectric constant was known to decrease further. Unlike conventional amorphous fluorinated carbon thin films, the present invention is characterized by exhibiting high-k characteristics. Accordingly, the amorphous fluorinated carbon thin film of the present invention is characterized by having a dielectric constant of 10 or more, and preferably 40 or more, more preferably 60 or more, which surpasses the dielectric constants of conventional Hf-based, Zr-based, or Ti-based oxide films.

The amorphous fluorinated carbon thin film of the present invention has very low surface roughness due to its amorphous structure, and the rms surface roughness is 5 nm or less, preferably 3 nm or less, more preferably 2 nm or less. Due to the low surface roughness, an ultra-thin film with a thickness of 10 nm or less can be formed without pinholes, and low leakage current and high insulation strength characteristics can be implemented.

While conventional high-k materials are difficult to apply to devices with nodes of 10 nm or less due to high leakage current, low insulation strength, and high CV hysteresis characteristics, the amorphous fluorinated carbon thin film of the present invention not only has a high dielectric constant value but also exhibits excellent electrical characteristics. Based on an equivalent oxide thickness of 0.1 nm, the thin film of the present invention has a leakage current of 10 A/cm² or less at an applied voltage of 1 V, an insulation strength of 10 MV/cm or more, and a CV hysteresis of 5 mV or less, making it useful even in devices of 10 nm or less.

Another aspect of the present invention relates to a method for manufacturing an amorphous fluorinated carbon thin film having a dielectric constant of 10 or more, comprising, (A) positioning a substrate in a plasma reactor; (B) introducing a first gas comprising fluorocarbon gas and a second gas comprising inert gas into the reactor; and (C) generating plasma in the reactor; wherein at least one of the temperature of the reactor, pressure, flow rate of the first gas, flow rate of the second gas, and plasma intensity is controlled to grow an amorphous thin film having a dielectric constant of 10 or more.

In the present invention, the plasma reactor refers to one that induces the reaction of reaction gases by generating plasma in the reactor, for example, plasma-enhanced chemical vapor deposition (PE-CVD) or inductively coupled plasma chemical vapor deposition (ICP-CVD), electron cyclotron resonance chemical vapor deposition (ECR-CVD) reactor. Plasma generates a large amount of highly reactive radicals from reaction gases, enabling thin film formation even at low temperatures. Although ICP-CVD is described as an example in the following examples, it is not limited thereto.

In the present invention, any substrate commonly used in thin film manufacturing may be used as the substrate. For example, it includes not only substrates for semiconductor device manufacturing such as silicon, glass, metal, and metal oxide substrates, but also substrates with active layers formed thereon, and substrates with graphene and two-dimensional nanomaterial layers such as MoS₂, MoSe₂, WS₂, WSe₂ formed thereon. According to the present invention, since no separate catalyst layer is required for the growth of amorphous fluorinated carbon thin film, the amorphous fluorinated carbon thin film can be directly deposited on the substrate to be layered without undergoing a separate transfer process. However, it does not exclude forming the thin film by transferring to another substrate after growing the amorphous fluorinated carbon thin film on the substrate. Furthermore, since film growth is possible at temperatures below 400° C., even in the case of polymer substrates such as polyimide, film growth is possible without damaging the substrate.

The manufacturing method of the present invention may further include a step of cleaning the substrate prior to step (A). The substrate cleaning can be performed using an appropriate method depending on the type of substrate material, and through this substrate cleaning step, not only can a surface state favorable for thin film growth be implemented, but also interfacial defects with the grown thin film can be reduced, resulting in excellent interfacial properties.

The characteristics of the amorphous fluorinated carbon thin film forming the high-k film are determined by the temperature of the reactor, pressure, flow rate of the first gas, flow rate of the second gas, and plasma intensity, and by controlling each variable, an amorphous fluorinated carbon thin film having a dielectric constant of 10 or more can be grown. Each variable is described in detail below. It is natural that the optimized absolute values of each variable may vary depending on each equipment, and it will be easy to manufacture a thin film with appropriate thickness, dielectric constant, and surface roughness for the intended use by referring to the following description of variables.

The first gas comprises a fluorocarbon gas. Any fluorocarbon gas that can form a fluorinated carbon thin film by plasma can be used, and carbon that can be used for graphene manufacture by chemical vapor deposition at high temperatures, for example, compounds selected from the group consisting of methane, ethane, propane, ethylene, acetylene, propylene in which hydrogen is substituted with fluorine can be used. The substitution of hydrogen with fluorine includes not only the substitution of all hydrogen atoms constituting the compound with fluorine but also partial substitution of hydrogen with fluorine. For example, compounds in which hydrogen of methane is substituted with fluorine include not only CF₄ used in the examples but also CHF₃, CH₂F₂, CH₃F. When the fluorocarbon contains hydrogen atoms, hydrogen along with fluorine can be trapped by dangling bonds in the thin film. Also, it does not exclude fluorocarbons other than the compounds mentioned above.

The second gas comprises an inert gas and acts as a carrier gas that controls the pressure in the reactor and the concentration of fluorocarbon. The second gas may further comprise hydrogen. Even when hydrogen is included in the second gas, hydrogen can be trapped along with fluorine by dangling bonds. Therefore, when hydrogen is included in the second gas, the ratio of fluorine and hydrogen trapped by dangling bonds in the thin film can be controlled by adjusting the volume ratio of the fluorocarbon gas in the first gas and the hydrogen gas in the second gas. The volume ratio of fluorocarbon gas in the first gas to hydrogen gas in the second gas can be set to 100:0~1:50. It is natural that as the volume ratio of hydrogen gas increases, the ratio of hydrogen compared to fluorine trapped by dangling bonds increases, and if the volume ratio of hydrogen gas to fluorocarbon gas exceeds 1:50, the trapping ratio of fluorine may become too low.

The volume ratio of the first gas to the second gas can be, for example, 1:1~1:100. If the ratio of the second gas is too high compared to the first gas, thin film growth may be too slow or difficult, and if the ratio of the second gas is too low, the film surface may become rough, degrading surface characteristics.

When plasma is applied in the presence of fluorocarbon gas, a fluorinated carbon thin film is formed on the substrate. It is already well known that in the deposition of carbon thin films using carbon gas, high-quality graphene films are formed at high temperatures above 900° C., and as the temperature decreases, dangling bonds increase and the crystallinity of the graphene film decreases. In the manufacture of the thin film of the present invention, the characteristics of the generated thin film also changed according to the temperature of step (C). At high temperatures, graphene is formed, and as the temperature decreases, nano-graphite containing nano-graphene crystals in the amorphous thin film is formed, and when the thin film manufacturing temperature is further lowered, the high-k amorphous fluorinated carbon thin film of the present invention was formed. Although the high-k characteristics of thin films manufactured at room temperature~400° C. are described in the following examples, since they may vary depending on other reaction conditions such as the equipment used, fluorocarbon gas concentration, pressure in the reactor, and plasma intensity, it is meaningless to limit their values to specific values, and considering various conditions, it is preferable to control the reaction temperature at 20~700° C.

In step (C), it is preferable that the pressure in the reactor is 0.1~10 Torr so that plasma discharge can be smoothly performed. If the pressure is too high, plasma maintenance becomes difficult, lowering thin film deposition efficiency, and if the pressure is too low, process efficiency decreases.

The intensity of plasma also affects the characteristics of the generated thin film. It is preferable that the intensity of the plasma is controlled in the range of 100 W~1,000 W. As the intensity of plasma increases, the growth rate of the thin film increases, surface roughness decreases, and the dielectric constant tends to increase (data not shown), therefore intensities above 1,000 W are not excluded. Furthermore, when the plasma intensity is low, the thickness or surface roughness of the thin film can be controlled by increasing the deposition time, and the dielectric constant can also change accordingly. Therefore, intensities below 100 W are also not excluded.

The optimal temperature, pressure, flow rate of the first gas, flow rate of the second gas, and plasma intensity of the reactor are factors that affect each other, so even if one parameter shows an optimal value at a specific value when other values are fixed, it is natural that the absolute value may change when other variables are adjusted.

The present invention aims to confirm and utilize the high dielectric properties of amorphous fluorinated carbon thin films, which have not been previously known, and can be easily implemented by skilled artisans by adjusting the conditions to achieve optimal characteristics, including desired thickness, dielectric constant, and surface roughness, based on the intended application of the amorphous fluorinated carbon thin film and the design of other components.

Another aspect of the present invention relates to a high-k film consisting of the amorphous fluorinated carbon thin film having a dielectric constant of 10 or more.

Yet another aspect of the present invention relates to a semiconductor device characterized by comprising the amorphous fluorinated carbon thin film having a dielectric constant of 10 or more. The high-k thin film can be, for example, a gate insulating film requiring a dielectric. Examples of the semiconductor device of the present invention include memory devices or logic devices. The high-k film of the present invention can be applied not only to thin film transistors but also as a dielectric film of capacitors. That is, it can be applied as an interlayer insulating dielectric film in semiconductor-metal or metal-metal laminated structures in MIS (Metal-Insulator-Semiconductor) devices or MIM (Metal-Insulator-Metal) devices.

As described above, the high-k amorphous fluorinated carbon thin film manufactured by the method of the present invention exhibits significantly higher dielectric values than SiO₂ and conventional Hf- or Zr-based oxides while maintaining very low leakage current and high dielectric strength characteristics, making it more advantageously applicable to semiconductors below the 10 nm node.

Furthermore, since the high-k carbon thin film of the present invention does not require a catalyst layer, it can be deposited directly onto the desired substrate without requiring a transfer process, resulting in excellent interfacial characteristics that can improve semiconductor device performance. Additionally, since the formation of the high-dielectric film is possible at low temperatures below 400° C., it can be applied to flexible devices that are sensitive to heat.

### BRIEF DESCRIPTION OF THE DRAWINGS

FIG. 1 is a Raman spectrum of thin films grown at different deposition temperatures.

FIG. 2 is an AFM image of an amorphous fluorinated carbon thin film.

FIG. 3 is an IR spectrum of thin films according to deposition temperature.

FIG. 4 is an XPS spectrum of thin films according to deposition temperature.

FIG. 5 is a C—V curve of amorphous fluorinated carbon thin films according to deposition temperature.

FIG. 6 is an HR-TEM image showing the interface between the Si substrate and the amorphous fluorinated carbon thin film.

FIG. 7 is a graph showing the thickness and dielectric constant of thin films according to deposition temperature.

FIG. 8 is a J-V curve of amorphous fluorinated carbon thin films according to deposition temperature.

### DETAILED DESCRIPTION

The following examples are provided to describe the present invention in more detail. However, these examples are merely illustrative to facilitate explanation of the technical content and scope of the present invention, and the technical scope of the present invention is neither limited nor altered thereby. It would be apparent to those skilled in the art that various modifications and variations are possible within the scope of the technical concept of the present invention based on these examples.

### EXAMPLE

### Example 1: Preparation of Amorphous Fluorinated Carbon Thin Film

An amorphous fluorinated carbon thin film was deposited on an n-type crystalline Si (100) substrate by ICP CVD (Inductively-coupled plasma chemical vapor deposition) using CF₄ gas and hydrogen/argon mixed gas under the following conditions. Specifically, 10 sccm of CF₄ gas and 100 sccm of hydrogen/argon mixed gas (10% hydrogen) were each introduced into the reactor. The Si substrate was first cleaned with 10% HF solution for 30 seconds according to the standard cleaning method, washed with DI water, and then used. During deposition, the pressure was fixed at 1 Torr, plasma power at 400 W, and deposition time at 30 minutes, while the deposition temperature was controlled in the range from room temperature to 400° C. to observe temperature effects.

### Example 2: Evaluation of Carbon Thin Film Characteristics According to Deposition Temperature

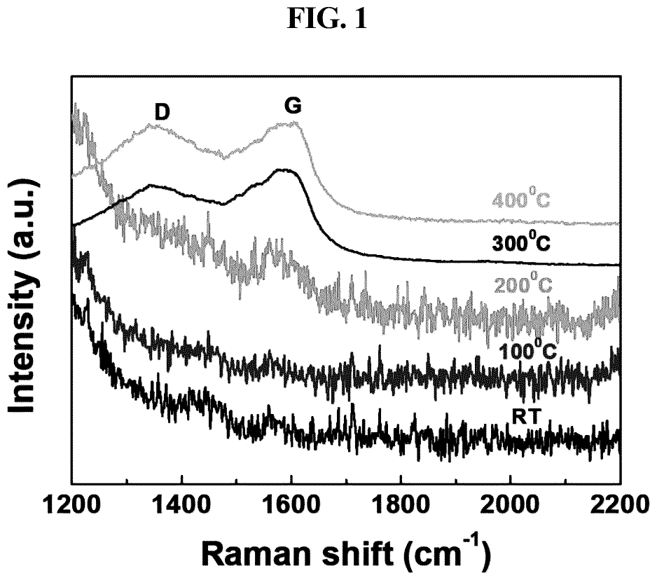

Raman spectra were observed for thin films formed at different deposition temperatures, and the results are shown in FIG. 1. The Raman spectra of samples deposited at low temperatures of room temperature or 100° C. showed only the G band at 1575 cm⁻¹, indicating the formation of completely disordered amorphous fluorinated carbon (a-C: F) thin films consisting mostly of disordered hexagonal rings or rings of other orders and almost completely sp²-bonded. In samples deposited at 200° C., the intensity of the G peak increased significantly, and as the deposition temperature was further increased to 300° C. and 400° C., the G peak shifted from 1575 cm⁻¹ to 1599 cm⁻¹, and a new D peak was observed, indicating graphitization of the amorphous carbon thin film. The appearance of the D peak indicates that the amorphous carbon is aligned but has a disordered structure of graphite. The generation of the D peak and the shift of the G peak suggest a decrease in the sp³/sp² ratio, and it was expected that the dielectric characteristics of the amorphous fluorinated carbon thin film could be controlled through changes in the sp³/sp² ratio.

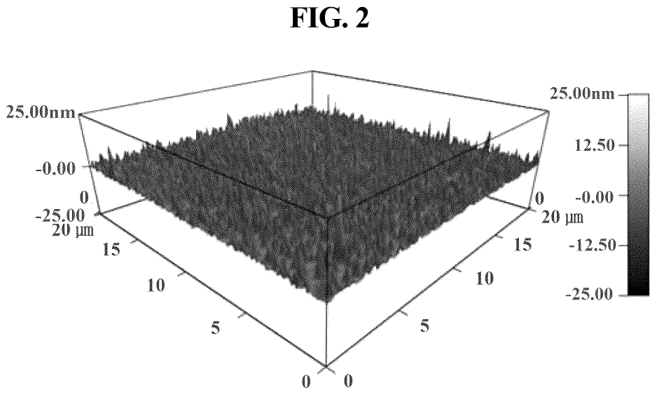

FIG. 2 is an AFM (Asylum Research, MFP-3D) image of an amorphous fluorinated carbon thin film grown directly on a Si substrate, confirming the growth of a uniform, pinhole-free smooth thin film. The surface roughness (root-mean-square roughness) value of the thin film was 1.4 nm.

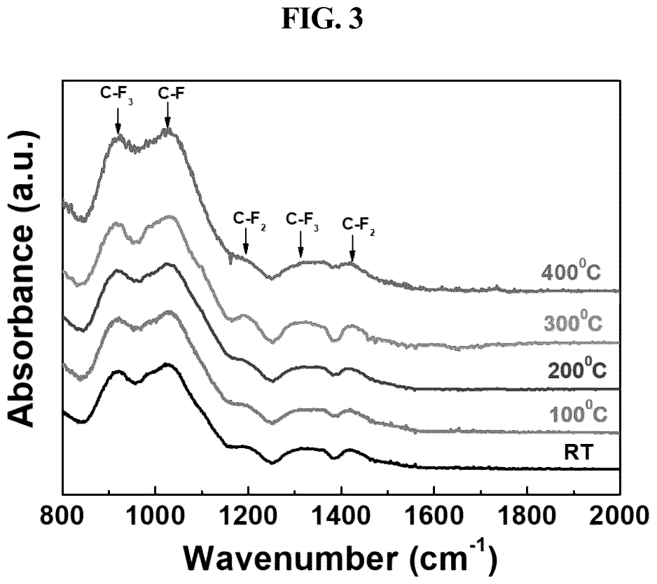

The chemical structure of the produced amorphous fluorinated carbon thin film was confirmed by FTIR (Nicolet 6700 Fourier transform infrared spectrometer). FIG. 3 shows the IR spectra of thin films according to deposition temperature, with all films showing similar spectra regardless of growth temperature. The strong peak at 10³⁰ cm⁻¹ corresponds to the asymmetric stretching of F atoms along the direction parallel to the C—F bond. The absorption bands at 923 cm⁻¹ and 1314 cm⁻¹ are attributed to C—F₃ stretching, and the absorption bands at 1192 cm⁻¹ and 1314 cm⁻¹ are attributed to symmetric and asymmetric stretching of C—F₂. Therefore, the FTIR spectra confirmed that C—F, C—F₂, and C—F₃ bonds exist in all films produced at each temperature, and thus the produced films are amorphous fluorinated carbon thin films with fluorine trapped in dangling bonds.

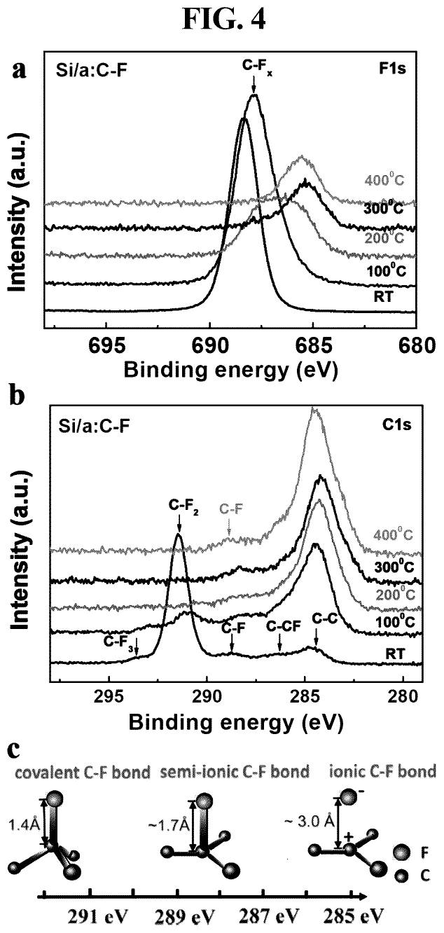

The chemical bonding in the thin films was further confirmed by XPS (K-Alpha X-ray photoelectron spectrometer) measurements. As shown in FIG. 4a, as the growth temperature of the thin film increased, the F/C ratio decreased, and the peak position for C—Fₓ bonds in the Fis spectrum shifted to lower energy from 688.3 eV to 685.4 eV. In particular, the XPS spectra showing Cis binding energy shown in FIG. 4b exhibited significant differences according to the growth temperature of the thin film. In the XPS spectrum of the thin film deposited at room temperature, peaks for C—F, C—F₂, and C—F₃ bonds were dominant, but when the deposition temperature increased to 100° C., the C—C peak increased dramatically and the C—F peak gradually increased while the C—F₂ and C—F₃ peaks decreased significantly. As the deposition temperature further increased to 200, 300, and 400° C., peaks due to C—C and C—F bonds became predominant. As shown in FIG. 4c, C—F bonds have the longest bond length of 3.0 Å compared to C—F₂ bonds (1.7 Å) or C-F₃ bonds (1.4 Å). Therefore, from the predominance of C—F bonds in the amorphous fluorinated carbon thin film, it can be expected to enhance both the dipole moment and the dielectric characteristics of the thin film.

### Example 3: Evaluation of Electrical Properties of Amorphous Fluorinated Carbon Thin Film

The electrical properties of the amorphous fluorinated carbon thin film were evaluated by fabricating an MIS device using the amorphous fluorinated carbon thin film of the present invention as a dielectric layer. Specifically, an MIS device was fabricated by forming circular Ti (5 nm)/Au (200 nm) electrodes by DC sputtering on the amorphous fluorinated carbon thin film grown on a Si substrate according to the method of Example 1.

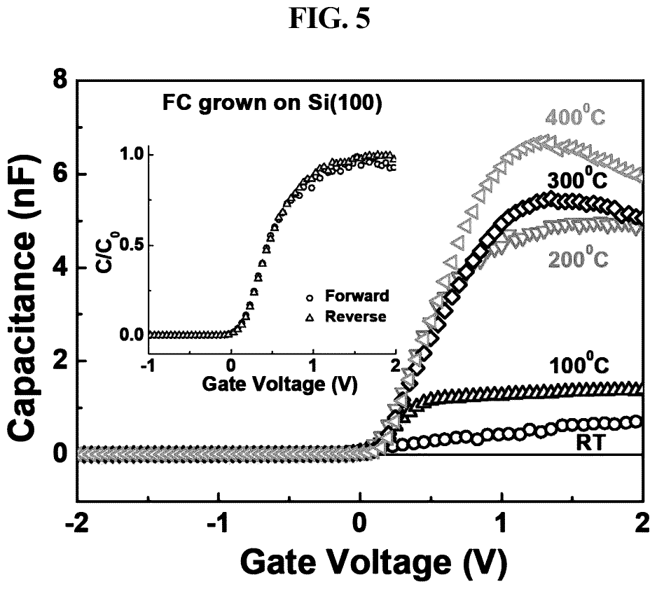

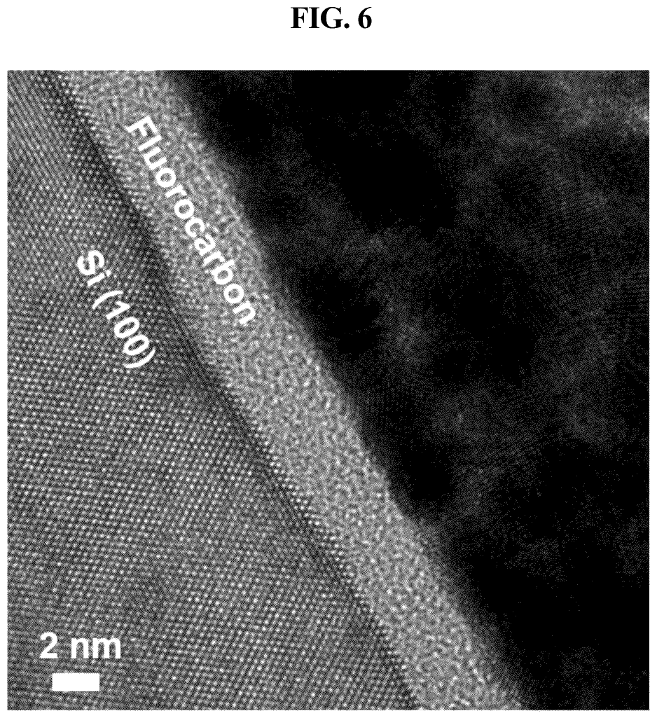

FIG. 5 shows the C—V curves of the amorphous fluorinated carbon thin film measured from the fabricated MIS device, demonstrating that the capacitance increases significantly as the film growth temperature increases. In the inset graph, o represents values measured in the forward direction from −2 V to 2 V, and A represents values measured in the reverse direction from +2 V to −2 V. The hysteresis in the C—V loops for all samples showed values close to zero (<5 mV). The very small hysteresis value indicates that the trapped charge density at the interface between the amorphous fluorinated carbon thin film and the Si substrate is very low. The excellent interfacial characteristics can be explained by (i) the formation of fluorinated dangling bonds at the Si interface during the growth of the amorphous fluorinated carbon thin film by ICP-CVD and (ii) the absence of an interfacial oxide layer between Si and the amorphous fluorinated carbon layer, as confirmed by the HR-TEM image in FIG. 6.

The dielectric constant of the amorphous fluorinated carbon thin film can be calculated from the C—V curves using the following equation.

$$k = {dC}_{max} / {ε}_{0} A$$

where k is the dielectric constant, d is the thickness of the film, Cₘₐₓ is the accumulation capacitance, to is the permittivity in vacuum, and A is the area of the MIS device.

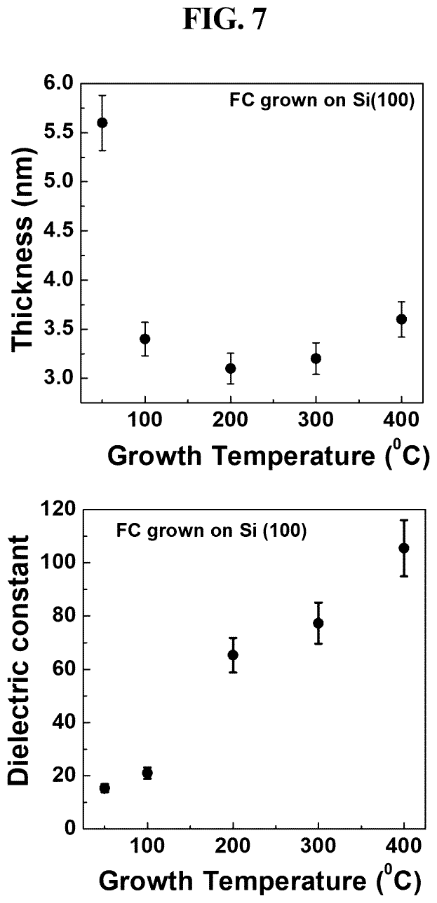

The upper graph in FIG. 7 shows the thickness of amorphous fluorinated carbon thin films grown at each deposition temperature measured using an ellipsometer M-2000, indicating that the film grown at room temperature had a thickness of 5.5 nm while films grown at 100-400° C. had thicknesses of 3-3.5 nm. The dielectric constants calculated from the film thicknesses are plotted against deposition temperature in the lower part of FIG. 7. The dielectric constant showed a slight increase for the film deposited at 100° C. compared to the film deposited at room temperature, but showed a dramatic increase at deposition temperatures of 200° C. and above. These results are consistent with the results of the Raman spectra and XPS spectra shown in FIG. 1 and FIG. 3. The dielectric constant of the amorphous fluorinated carbon thin film grown at 400° C. was 105, which is significantly higher than not only the previously reported dielectric constants of 20-30 for Hf- and Zr-based oxides but also the dielectric constant of 90 for the amorphous carbon thin film reported by the present inventors in Registered Patent No. 10-2314727 and others.

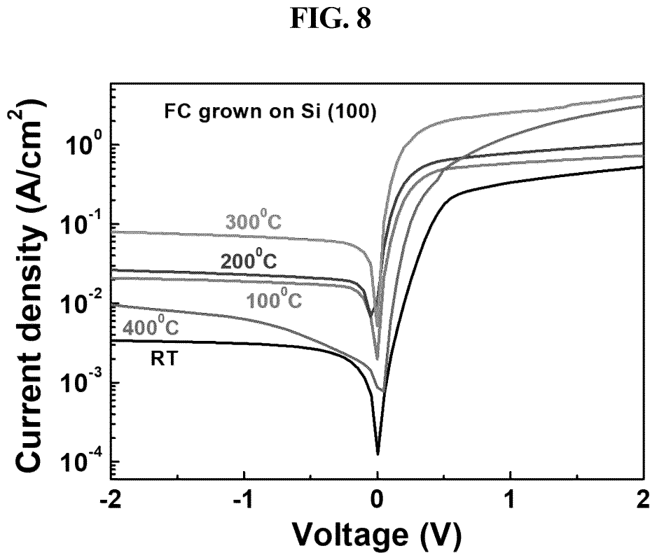

An important requirement for high-k dielectrics is low leakage current density and high dielectric strength. To verify the practical utility of the amorphous fluorinated carbon thin film as an actual gate dielectric material, J-V measurements were performed and the results are shown in FIG. 8. The amorphous fluorinated carbon thin film grown at 400° C., which showed the highest dielectric constant of 105, exhibited excellent MIS leakage current density of approximately 5 A/cm² at an applied voltage of 1V for an equivalent oxide thickness (EOT) of 0.1 nm. Furthermore, no breakdown phenomenon was observed up to 3V, the voltage applied for J-V measurements, confirming that the dielectric strength has a high value of at least 10 MV/cm. These leakage current and dielectric strength values are at least equal to or superior to recently reported high-k oxides.

1. An amorphous fluorinated carbon thin film having a dielectric constant of 10 or more.

2. The amorphous fluorinated carbon thin film according to claim 1,
wherein fluorine is trapped in dangling bonds of the amorphous carbon thin film.

3. The amorphous fluorinated carbon thin film according to claim 2,
wherein hydrogen is further trapped in the dangling bonds of the amorphous carbon thin film.

4. The amorphous fluorinated carbon thin film according to claim 1,
wherein the rms surface roughness of the thin film is 5 nm or less.

5. The amorphous fluorinated carbon thin film according to claim 1,
wherein the leakage current is 10 A/cm² or less at an applied voltage of 1V and an equivalent oxide thickness of 0.1 nm.

6. The amorphous fluorinated carbon thin film according to claim 1,
wherein the dielectric strength is 10 MV/cm or more at an equivalent oxide thickness of 0.1 nm.

7. The amorphous fluorinated carbon thin film according to claim 1,
wherein the CV hysteresis is 5 mV or less.

8. A method for manufacturing an amorphous fluorinated carbon thin film, comprising:
(A) positioning a substrate in a plasma reactor;
(B) introducing a first gas comprising fluorocarbon gas and a second gas comprising inert gas into the reactor; and
(C) generating plasma in the reactor;
wherein at least one of the temperature of the reactor, pressure, flow rate of the first gas, flow rate of the second gas, and plasma intensity is controlled to grow an amorphous thin film having a dielectric constant of 10 or more.

9. The method according to claim 8,
wherein the reactor is a reactor for plasma-enhanced chemical vapor deposition, inductively coupled plasma chemical vapor deposition, or electron cyclotron resonance chemical vapor deposition.

10. The method according to claim 8,
wherein the fluorinated carbon thin film comprises both fluorine and hydrogen trapped in dangling bonds of the amorphous carbon thin film.

11. The method according to claim 8,
wherein the second gas further comprises hydrogen.

12. The method according to claim 11,
wherein the flow rates of the first gas and the second gas are controlled to achieve a volume ratio of fluorocarbon gas in the first gas to hydrogen gas in the second gas of 100:0 to 1:50.

13. The method according to claim 8,
wherein the temperature in the reactor is controlled within the range of 20 to 700° C.

14. The method according to claim 8,
wherein the pressure in the reactor is controlled within the range of 0.1 Torr to 10 Torr.

15. The method according to claim 8,
wherein the plasma intensity is controlled within the range of 100 W to 1,000 W.

16. The method according to claim 8,
wherein an oxide layer is absent at the interface with the substrate.

17. A high-k dielectric film consisting of the amorphous fluorinated carbon thin film according to claim 1.

18. A semiconductor device comprising the amorphous fluorinated carbon thin film according to claim 1.

19. The semiconductor device according to claim 18,
wherein the amorphous fluorinated carbon thin film is used as a gate insulating film.

20. The semiconductor device according to claim 18,
wherein the semiconductor device is a memory device or a logic device.

21. A capacitor device comprising the amorphous fluorinated carbon thin film according to claim 1.
